(19) United States
(12) Patent Application Publication
(10) Pub. No.: US 2008/0284534 A1
(43) Pub. Date: Nov. 20, 2008

(54) OSCILLATOR

(76) Inventor: Samir El Rai, Colorado Springs, CO (US)

Correspondence Address: Muncy, Geissler, Olds & Lowe, PLLC, P.O. BOX 1364, FAIRFAX, VA, 22038-1364, US

(21) Appl. No.: 12/120,792

(22) Filed: May 15, 2008

Related U.S. Application Data
(60) Provisional application No. 60/940,689, filed on May 29, 2007.

(30) Foreign Application Priority Data
May 15, 2007 (DE) 10 2007 022 999.4

(51) Int. Cl. H03B 5/12

(52) U.S. Cl. 331/117 FE

(57) ABSTRACT

An oscillator is provided that includes a plurality of excitation units for providing an excitation signal and a tank as an oscillation generating unit for generating an oscillation signal in response to the excitation signal, whereby the tank has terminals for providing the oscillator signal, whereby each excitation unit has at least one inductor, whereby the tank is coupled magnetically to the at least one inductor of each excitation unit, and whereby the excitation signal can be transmitted between the excitation units and the tank by means of the magnetic coupling.

This nonprovisional application claims priority to German Patent Application No. DE 10 2007 022 999.4, which was filed in Germany on May 15, 2007, and to U.S. Provisional Application No. 60/940,689, which was filed on May 29, 2007, and which are both herein incorporated by reference.

### BACKGROUND OF THE INVENTION

1. Field of the Invention

The present invention relates to the field of oscillation generation.

2. Description of the Background Art

Local oscillators, which, for example, are used as voltage-controlled oscillators (VCO; Voltage Controlled Oscillator), are required in many communications engineering systems. These oscillators generate an oscillator signal, which is needed both for downmixing and upmixing a received signal or a signal to be transmitted.

FIG. 10 shows a VCO circuit, which typically has two circuit units. The first circuit unit 1001 is a tank (LC resonant circuit), which is provided to generate an oscillation. The second circuit unit 1003 is an amplifier, which excites the tank.

The signal quality of the oscillator significantly influences the quality of a message transmission system. The most important properties of a VCO are its spectral purity, its output power, and its power efficiency. A measure of the spectral purity of an output signal of an oscillator is the phase noise PN.

The phase noise depends primarily on the following parameters: quality factor of the LC tank Q; amplitude A of the LC tank, which is the voltage difference between the nodes AP and AN, drawn in FIG. 10, during oscillation; and noise of the amplifier.

U.S. Patent No. 2006/0181355 A1 discloses a silicon bipolar VCO with a doubly coupled transmitter. U.S. Pat. No. 7,154,349 B2 describes a multi-band VCO with coupled inductors and a plurality of ports.

### SUMMARY OF THE INVENTION

It is therefore an object of the invention to provide an improved oscillator generation.

Accordingly, an oscillator with a plurality of excitation units for supplying an excitation signal is provided. The oscillator has a tank as the oscillation generating unit for generating an oscillation signal in response to the excitation signal. The tank has terminals for supplying the oscillator signal. Each excitation unit has at least one inductor.

The tank is magnetically coupled to at least one inductor of each excitation unit. The excitation signal can be transmitted between the excitation units and the tank by means of magnetic coupling.

An efficient concept for oscillation generation is preferably achieved by the transmission of the excitation energy via magnetic coupling between an excitation unit, e.g., an amplifier, and an oscillation generating unit, e.g., a tank.

An increase in the amplitude is advantageously achieved independent of the aforementioned factors. At the same time, an optimal operating amplitude and operating environment of the active components (e.g., the excitation unit) can be achieved, which results in better noise behavior and performance of these components.

The invention provides an oscillator with an excitation unit, e.g., an amplifier, for providing an excitation signal and an oscillation generating unit, e.g., a tank, for generating an oscillation signal in response to the excitation signal. The excitation signal is preferably transmitted from the excitation unit to the oscillation generating unit by means of at least one magnetic coupling.

The oscillator comprises a plurality of excitation units, whereby each of the excitation units can be coupled magnetically to the oscillation generating unit to transmit an excitation signal. The excitation units therefore supply via a plurality of magnetic couplings (e.g., parallel) the power required for generating oscillations. In each case, a magnetic or capacitive coupling can be provided between the excitation units according to another embodiment.

Each excitation unit comprises at least one inductor, whereby the oscillation generating unit has for each excitation unit at least one inductor, which is assigned to the respective excitation units. Each inductor of the respective excitation unit and the inductor, assigned to it, of the oscillation generating unit are preferably provided for magnetic coupling in each case.

According to an embodiment, each excitation unit and the oscillation generating unit are galvanically separated from one another both with respect to the DC voltage signals and the AC voltage signals, for example, with respect to the high-frequency signals.

According to another embodiment, each excitation unit and the oscillation generating unit are galvanically coupled with respect to the DC voltage signals (for example, via ground) and galvanically separated from one another only with respect to the AC voltage signals, for example, with respect to the high-frequency signals.

According to another embodiment, each excitation unit and the oscillation generating unit are connected to at least one nodal point at which a constant potential, particularly a virtual ground, predominates during oscillator operation.

According to an embodiment, each excitation unit and the oscillation generating unit each have an inductor, which can be coupled magnetically. The magnetic coupling is thereby realized via inductive elements, e.g., coils or also suitably arranged strip lines.

According to another embodiment, each excitation unit comprises an amplifier, e.g., a transistor amplifier, with at least one inductor, which is provided for the magnetic coupling with at least one inductor of the oscillation generating unit.

According to another embodiment, the oscillation generating unit comprises an LC circuit, which can be tuned and may have tunable capacitors and/or inductors, for tuning an oscillation frequency of the oscillator signal. In this case, at least one inductor of the LC circuit can be provided for the magnetic coupling.

According to another embodiment, the oscillation generating unit comprises terminals for providing the oscillator signal, which are galvanically separated from the excitation unit or are connected to at least one nodal point at which a constant potential, particularly a virtual ground, predominates during oscillator operation. Thus, the excitation path and the oscillation path are isolated from one another.

According to another embodiment, each excitation unit comprises a transistor amplifier circuit, a first inductor, and a second inductor, whereby the first and second inductors are connected to the transistor amplifier circuit and are provided for the magnetic coupling. Further, the oscillation generating unit comprises a third inductor and a fourth inductor, each of which is provided for magnetic coupling, whereby the second and fourth inductors are provided for magnetic coupling, and whereby the first and third inductors are provided for magnetic coupling. In this case, the excitation energy is transmitted via two magnetic couplings.

According to another embodiment, the first and second inductors are connected conductively via a nodal point at which a potential, e.g., the ground potential, can be applied. The third and fourth inductors are connected, for example, in series in this case.

According to another embodiment, each excitation unit comprises at least one amplifier circuit, whereby the amplifier circuit comprises a first transistor and a second transistor, whereby a first terminal of the first transistor is connected to a control terminal of the second transistor, and whereby a first terminal of the second transistor is connected to a control terminal of the first transistor. Additional capacitance, which also has an effect on the resulting oscillation frequency, is produced simultaneously by this cross connection.

The first terminal of the first transistor is preferably connected to a first inductor of each excitation unit, the second terminal of the second transistor is preferably connected to a second inductor of each excitation unit, and the second terminals of the first and of the second transistors are preferably connected to one another.

The first terminals, e.g., can be drain or source terminals of the transistors, whereby the control terminals can be, e.g., gate terminals.

According to another embodiment, each excitation unit comprises a first conductive structure, e.g., a strip line. The oscillation generating unit comprises a second conductive structure, e.g., a strip line. In this case, the first and second conductive structures are arranged to provide the magnetic coupling. The conductive structures for this purpose form, e.g., magnetically couplable inductors.

According to another embodiment, at least one of the excitation units comprises a first conductive structure, which is surrounded in least partially by a second conductive structure of the oscillation generating unit. For example, the second conductive structure, e.g., a strip line, forms an open loop, within which the first conductive structure is arranged, so that the magnetic coupling can arise.

According to another embodiment, each excitation unit comprises a first amplifier and a second amplifier, whereby the first amplifier and second amplifier are connected in parallel via conductive structures, e.g., strip lines. In this case, the oscillation generating unit also comprises a conductive structure, which is provided for magnetic coupling with the conductive structure of the excitation unit.

According to another embodiment, the conductive structures of the excitation unit are connected conductively via another conductive structure, which forms a rib, for example.

According to another embodiment, the first amplifier and second amplifier are connected parallel to the other conductive structure.

The oscillator is preferably tunable, whereby the oscillation generating unit and/or the excitation unit may have tunable inductors and/or capacitors.

According to another embodiment, the oscillation generating unit comprises at least one conductive structure, which surrounds at least partially at least one conductive structure of the excitation unit for the magnetic coupling, for example, as an open loop.

According to another embodiment, the conductive structures of the respective excitation unit are connected galvanically separated at least with respect to the HF signals or connected to at least one nodal point at which virtually a constant potential, particularly virtual ground, predominates during operation of the oscillator.

According to another embodiment, the excitation units and/or the oscillation generating unit are made as differential circuits.

A method for generating an oscillation comprises the steps of providing an excitation signal by a plurality of excitation units and generation of an oscillation signal by an oscillation generating unit in response to the excitation signal, whereby the excitation signal is transmitted for each excitation unit between the excitation units and the oscillation generating unit by means of magnetic coupling.

Other process steps result directly from the functionality of the oscillator.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 illustrates a block diagram of an oscillator;

FIG. 2 illustrates an oscillator;

FIGS. 3a and 3b illustrate an oscillator;

FIGS. 4a and 4b illustrate an oscillator;

FIG. 5 illustrates a chip pattern of an oscillator;

FIG. 6 illustrates an oscillator;

FIG. 7 illustrates an oscillator;

FIG. 8 illustrates an oscillator;

FIG. 9 illustrates an oscillator; and

FIG. 10 illustrates an oscillator.

### DETAILED DESCRIPTION

FIG. 1 shows a block diagram of an oscillator with an excitation unit 101 for providing an excitation signal and an oscillation generating unit 103 for generating an oscillation signal in response to the excitation signal. Excitation unit 101 has an inductor 105, which is assigned an inductor 107 of oscillation generating unit 103. Inductors 105 and 107 are designed to supply a magnetic coupling 109, over which the excitation signal is transmitted from excitation unit 101 to oscillation generating unit 103. Oscillation generating unit 103 comprises further at least one output 110 at which the oscillation signal is provided.

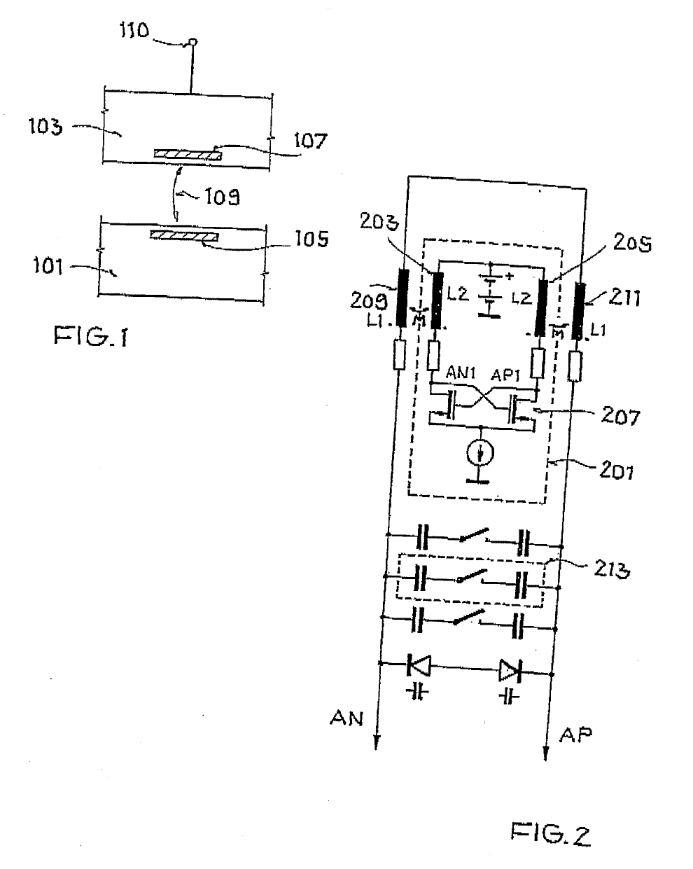

FIG. 2 shows an oscillator with an excitation unit 201, which comprises a first inductor 203, a second inductor 205, a transistor amplifier circuit 207 comprising two coupled transistors and a current source, connected to ground, and two outputs AN1 and AP1. Output AN1 is coupled via an optional resistive element (e.g., an optional resistor) to first inductor 203, and output AP1 is coupled via another optional resistive element (e.g., an optional resistor) to second inductor 205. Inductors 203 and 205 are further connected via a nodal point at which, e.g., the ground potential or another potential (e.g., Vdd) can be applied.

The oscillator comprises further an oscillation generating unit with a third inductor 209 and a fourth inductor 211, which is connected in series to third inductor 209. Inductor 209 is connected via an optional resistive element (e.g., an optional resistor) to a first output AN of the oscillation unit, and inductor 211 is connected via an optional resistive element (e.g., an optional resistor) to a second output AP of the oscillation unit. Further, at least one capacitive network 213, which has two capacitors connected in series via a switch, is connected between outputs AN and AP. Further, a diode circuit comprising at least two antiseries-connected diodes, each of which simulates a capacitor, is arranged between outputs AN and AP.

In this topology, the coupling of the power generated by the active components occurs magnetically in resonant circuit 201.

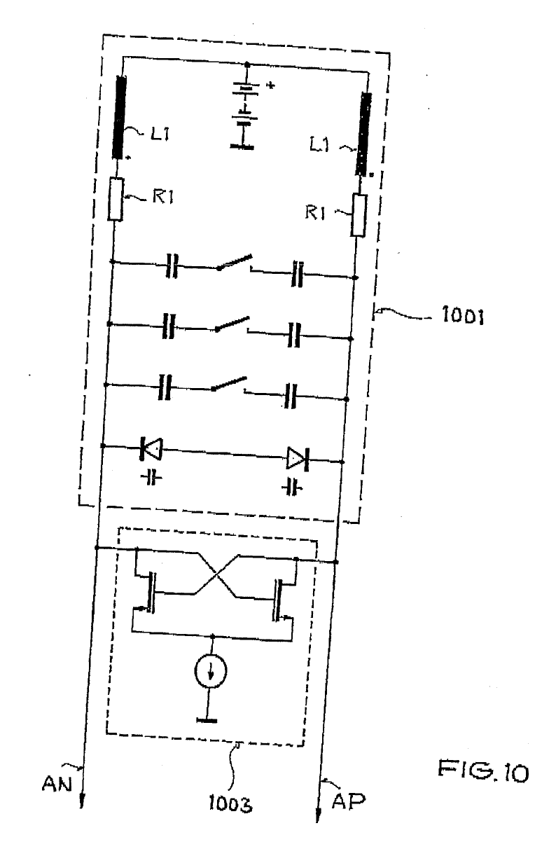

If the value L2 of inductors 203 and 205 is equal to the value L1 of inductors 209 and 211 and if the magnetic coupling M is equal to 1, the same properties are achieved in this topology as in the topology of FIG. 10.

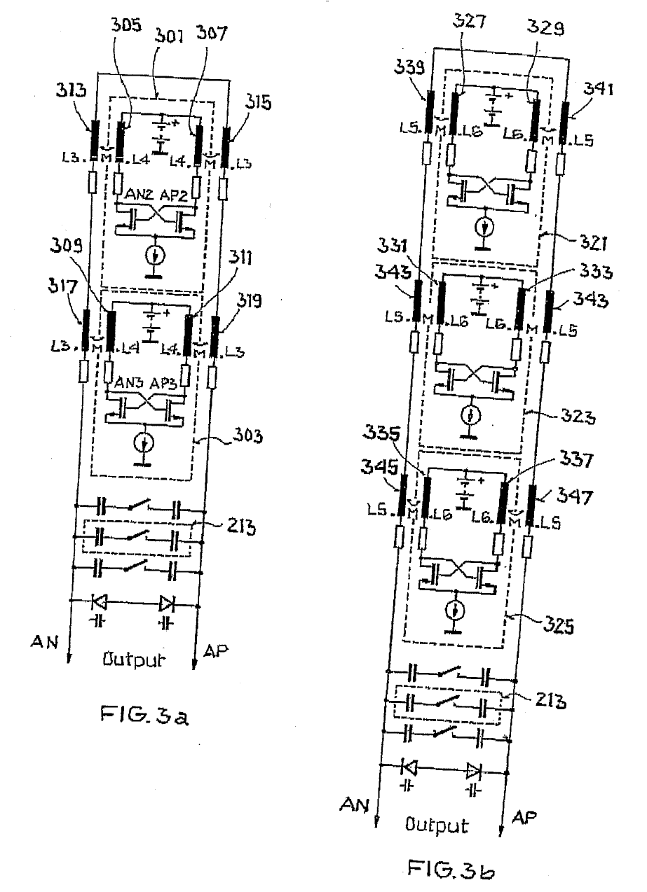

Oscillators for realizing a VCO with high amplitudes are shown in FIGS. 3a and 3b.

FIG. 3a shows an oscillator with a first excitation unit 301 and a second excitation unit 303, whose structures in each case correspond to the structure of the excitation unit 207 of FIG. 2. Each excitation unit 301 and 303 comprises a transistor amplifier circuit with coupled transistors, optional resistive elements, and a current source. Excitation unit 301 comprises two inductors 305 and 307 coupled via a nodal point at which a (virtual) ground potential can be applied, and excitation unit 303 comprises two inductors 309 and 311 coupled via a nodal point at which a (virtual) ground potential can be applied.

The oscillator comprises further an oscillation generating unit with series-connected inductors 313 and 315. Inductor 313 is coupled via an optional resistor to an inductor 317, which is coupled via an optional resistor to a first output AN of the oscillator. Inductor 315 is coupled via an optional resistor to an inductor 319, which is coupled via an optional resistor to a second output AP. At least one capacitive circuit 213 comprising at least two capacitors coupled via a switch and a diode circuit comprising two antiseries-connected diodes are arranged between outputs AN and AP.

The magnetic coupling between the excitation units 301, 303 and the oscillation generating unit is realized via the inductor pairs 305 and 313, 307 and 315, 309 and 311, and 313 and 319.

An advantage of the exemplary embodiment of FIG. 3a is that the DC operating current for the transistors of the excitation units 301, 303 in this topology flows not through inductors 313, 315, 317, 319 (L3), but through inductors 305, 307, 309, 311 (L4). This separation of the currents (AC and DC) has quality advantages at high current densities.

The amplitude of the oscillation signal between the terminals AP and AN is preferably greater than the amplitude between the terminals AP2 and AN2 and preferably greater than the amplitude between the terminals AP3 and AN3.

FIG. 3b shows an oscillator with a first excitation unit 321, a second excitation unit 323, and the third excitation unit 325, whose structures in each case correspond to the structure of the excitation unit of FIG. 2. Each excitation unit 321, 323, 325 comprises a transistor amplifier circuit with coupled transistors, optional resistive elements, and a current source. Excitation unit 321 comprises two inductors 327 and 329 coupled via a nodal point at which a (virtual) ground potential can be applied. Excitation unit 323 comprises two inductors 331 and 333 coupled via a nodal point at which a (virtual) ground potential can be applied. Excitation unit 325 comprises two inductors 335 and 337 coupled via a nodal point at which a (virtual) ground potential can be applied.

The oscillator comprises further an oscillation generating unit with series-connected inductors 339 and 341. Inductor 339 is coupled via an optional resistor to an inductor 343, which is coupled via an optional resistor to an inductor 347. Inductor 347 is coupled via an optional resistor to a first output AN of the oscillation generating unit. Inductor 341 is coupled via an optional resistor to an inductor 343, which is coupled via an optional resistor to an inductor 345. Inductor 345 is coupled to a second output AP. At least one capacitive circuit 213 comprising at least two capacitors coupled via a switch and a diode circuit comprising two antiseries-connected diodes are arranged between outputs AN and AP.

The magnetic coupling between the excitation units and the oscillation generating unit is realized via the inductor pairs 327 and 339, 329 and 341, 343 and 331, 333 and 343, 345 and 335, and 337 and 347.

In the case of the topology of FIG. 3a, approximately the same oscillation frequency as with the structure of FIG. 10 is obtained at the same inductance values L3=L4=L1=L2 (the inductance preferably remains constant overall) and M=1. The oscillation amplitude in the tank (between the terminals AP and AN) is twice as high, however. In this case, the signal amplitude at the active components (in each case between terminals AP and AN) is the same as in the topology of FIG. 10. The values of the inductances and the coupling factors can differ, however, from the aforementioned exemplary values.

The topology of FIG. 3b is based on the same principle as the topology of FIG. 3a. In contrast thereto, however, a tripling of the oscillation amplitude at the same operating amplitudes of the active components is achieved.

The resistive elements or resistors mentioned in the aforementioned exemplary embodiments are optional. The signals are preferably fed directly into the inductors shown in FIGS. 2, 3a, and 3b. The resistors shown there can also be parasitic ohmic resistors of the inductors.

The tank amplitude A has a decisive effect on the phase noise. An increase in this amplitude according to exemplary embodiments 3a or 3b reduces the phase noise, which is attributed to the improvement of the signal-to noise ratio in the oscillating tank, therefore the ratio of the oscillation energy to noise energy in the tank. Contrary to the exemplary embodiment of FIG. 10, this amplitude is also not transmitted to the active components. As a result, in the exemplary embodiment of FIG. 3b, the surprising effect is achieved that no amplitude limitation occurs, because the active transistors do not go energetically into saturation.

The aforementioned oscillation generating concept of the exemplary embodiment of FIG. 3b therefore has the following effects:
The possibility of realizing high amplitudes by the tank is not limited by the employed technology. MOS technologies with small gate lengths of 0.09μ and 0.18μ can be cited as an example, which due to technology do not allow a voltage drop across the gate of more than 2.5 V because of the tunneling current or breakdown.
A lower or no amplitude limitation occurs that would be caused by the saturation of the active components. This reduces the generation of an oscillation of higher undesirable harmonics also by a conversion of the available energy. A greater efficiency is therefore achieved.
The active components can be operated in an operation with a smaller swing compared with a large-signal operation. The noise of the components, particularly the amplitude noise of the active components, is reduced in this operation. The amplitude noise is converted to a lesser extent into phase noise via modulation compared with large-signal operation and therefore leads to a lower phase noise overall.

In addition, noise modeling and general power modeling of the active components are clearly simpler compared with large-signal operation, which simplifies prediction of the phase noise properties because of a greater simulation accuracy and leads to smaller differences between simulation and measurement.

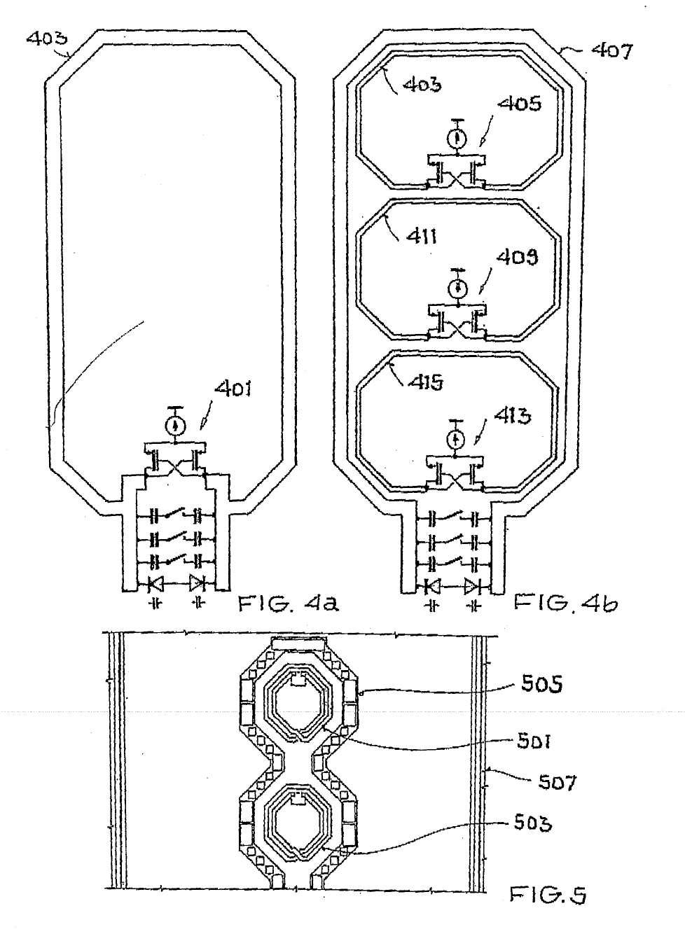

FIG. 4a shows a basic technology of an oscillator unit with an excitation unit 401, comprising an amplifier, and an oscillation generating unit, which comprises, e.g., a conductive structure 403, e.g., a strip line, which forms, e.g., a partially closed loop. Excitation unit 401, several capacitor networks with capacitors connected via a switch in each case, and a diode arrangement with two antiseries-connected diodes are connected in parallel between the outputs of the conductive structure.

FIG. 4b shows a realization of the structure of FIG. 3b. The structure shown in FIG. 4b, in contrast to the structure of FIG. 4a, comprises a plurality (e.g., three) of excitation units which are arranged within conductive structure 403 and are separated, e.g., galvanically from one another.

A first excitation unit comprises an amplifier 405, whose outputs are connected via a conductive structure 407, e.g., a strip line. The conductive structure 407 is provided for the magnetic coupling with the oscillation unit. For this purpose, conductive structure 407 comprises, for example, sections arranged parallel to the corresponding sections of conductive structure 403.

A second excitation unit comprises an amplifier 409, whose outputs are connected via a conductive structure 411, e.g., a strip line. The conductive structure 411 is provided for the magnetic coupling with the oscillation unit. For this purpose, conductive structure 411 comprises, for example, sections arranged parallel to the corresponding sections of conductive structure 403.

A third excitation unit comprises an amplifier 413, whose outputs are connected via a conductive structure 415, e.g., a strip line. The conductive structure 407 is provided for the magnetic coupling with the oscillation unit. For this purpose, conductive structure 415 comprises, for example, sections which are parallel to the corresponding sections of conductive structure 403.

The coupling M=1 can be realized only with difficulty without affecting the quality of the inductors. Expedient practical values for M are under 0.75 in amount. The following values can be used for the components: L3=100 pH, L4=240 pH, and M=0.6. Further, the capacitance of the total differential capacitance is, e.g., 1 pF. The resonance frequency of the tank (the oscillation generating unit) without the active components with the aforementioned is about, e.g., 8 GHz or about 10 GHz.

In designs according to FIG. 4a, the circuit oscillates, e.g., at 7.46 GHz. This is somewhat lower than 8 GHz and is due to the fact that the active components load the tank capacitively. The oscillation amplitude of the tank of the oscillator according to the invention is 3.3 V. This is the same as the amplitude of the active components.

With the design according to FIG. 4b, the circuit oscillates, e.g., at 7.7 GHz, therefore with a slightly higher oscillation frequency than in the topology according to FIG. 4a. The main reason for this is that the parasitic capacitances of the active components are a function of their amplitudes. When the active components are operated at a lower amplitude than in the exemplary embodiment of FIG. 4b, they have lower parasitic capacitances, which is advantageous for tunability. The oscillation amplitude of the tank, as in the exemplary embodiment of FIG. 4b, is, e.g., 4.3 V, whereas the amplitude at the active components is 2.2 V. For the exemplary embodiment of FIG. 4b, therefore, almost a doubling of the tank amplitude is achieved compared with the amplitude of the active components.

FIG. 5 shows a chip pattern of an oscillator with a first excitation unit 501, a second excitation unit 503, and an oscillation unit 505, which are arranged in the form of a conductive structure on a substrate 507. The spirally arranged conductive structures of the excitation units are each provided for magnetic coupling. The excitation units each comprise an amplifier, which is connected in each case to terminals, provided therefor, of the respective conductive structure (e.g., strip lines).

FIG. 6 shows an oscillator with an oscillation generating unit, which has a conductive structure 601, e.g., a strip line. The oscillation generating unit comprises further at least one capacitive circuit with two capacitors coupled via a switch and a diode circuit comprising two antiseries-connected diodes. The capacitive circuit and the diode circuit are arranged in parallel between the terminals of the conductive structure 601, whereby the terminals can be formed as bent structural sections.

Conductive structure 601 forms, for example, a partially closed loop, whereby two excitation units with a first amplifier circuit 603 and a second amplifier circuit 605 are arranged within the loop. The amplifier circuits 601, 602 of the two excitation units each comprise coupled transistors, which are connected via a current source to ground and are connected in parallel via a conductive structure to a first conductive section 607 and a second conductive section 609. The conductive sections 607 and 609 are connected via a conductive rib. The ends of conductive sections 607 and 609 are each arranged opposite to the terminal-forming ends 613 and 615 of the oscillation generating unit, at which the oscillation signal can also be provided. Conductive sections 607 and 609 are provided in each case for magnetic coupling with conductive structure 601.

The magnetic coupling with an optimized area requirement can be achieved with the structure shown in FIG. 6.

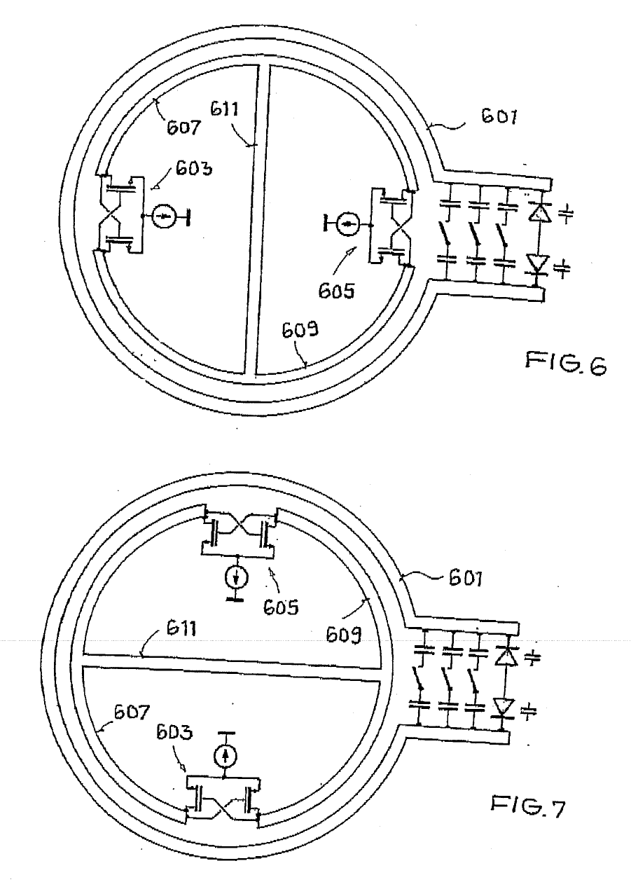

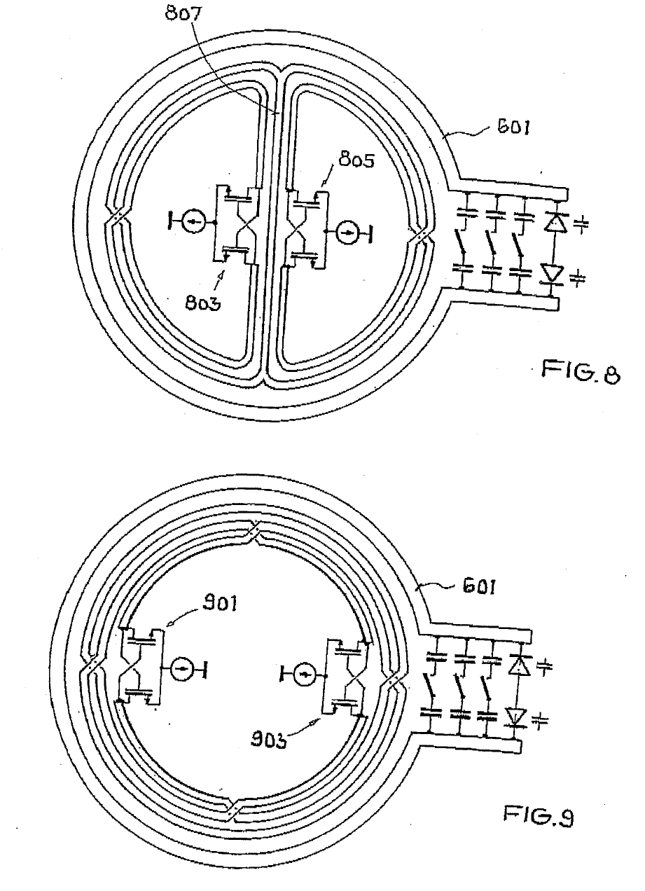

FIG. 7 shows the oscillator of FIG. 6 with two excitation devices rotated by 90 degrees. Rib 611 and terminal areas 613 and 615 are thereby arranged in parallel. An improved capacitive load is achieved by the exemplary embodiment of FIG. 7.

FIG. 8 shows an oscillator with two excitation units, which are arranged within the loop formed at least partially by conductive structure 601. Each excitation unit comprises a conductive structure and transistor amplifier circuits 803 or 805, which are connected in parallel by the conductive structure. The terminals of transistor amplifier circuits 803 and 805 are coupled in each case via twisted conductive structures, which are connected via a rib 807 running between amplifier circuits 803 and 805. In the exemplary embodiment of FIG. 8, each transistor can be operated at its optimal power operating point. The effect of noise, distortions, temperature, and substrate effects is reduced compared with the exemplary embodiment of FIG. 10. Nevertheless, a large signal amplitude can be achieved.

FIG. 9 shows an oscillator with two excitation units, arranged within the loop formed at least partially by conductive structure 601. Each excitation unit comprises a transistor amplifier circuit 901 or 903, whereby transistor amplifier circuits 901 and 903 are connected in parallel by a conductive structure. The terminals of transistor amplifier circuits 901 and 905 are coupled in each case via twisted conductive structures, which extend concentrically and in a spiral form and are also provided for the magnetic coupling with conductive structure 601. In the topology of the exemplary embodiment of FIG. 9, a higher inductance is achieved for the active components.

The conductive structures can be formed, e.g., as strip lines or microstrip lines.

The following sometimes surprising effects are achieved by the exemplary embodiment of FIG. 9:
the realization of higher tank amplitudes is no longer limited by the technology,
the supply voltage does not limit the amplitude,
the active components do not operate in large-signal operation,
smaller parasitic capacitances of the active components,
lower amplitude noise during large-signal operation,
lower amplitude noise, because C_{Activ} is a function of the amplitude,
better tunability by tuning of the capacitors,
higher harmonic suppression due the smaller operating amplitude of the active components,
higher harmonic suppression particularly of the third harmonic due to the energy transmission via the magnetic coupling,
the noise modeling and general performance modeling of the active components in this amplitude operation are very simple, which facilitates prediction of the PN properties by simulations,
quality advantages at high current densities, and
lower area requirement.

An oscillator according to the exemplary embodiments can be used, for example, in a data transmission system according to IEEE 802.16 (WiMax, Worldwide Interoperability for Microwave Access).

A transmitting/receiving device in this system has an antenna and a transmitting/receiving unit (transceiver) connected to the antenna. The transmitting/receiving unit comprises an HF front-end circuit, connected to the antenna, and a downstream IF/BB signal processing unit. Furthermore, the transmitting/receiving unit contains a transmit path connected to the antenna.

The HF front-end circuit amplifies a high-frequency radio signal, which is received by the antenna and lies spectrally within the microwave range between 3.4 and 3.6 GHz, and converts (transforms) it into a quadrature signal in an intermediate frequency range (intermediate frequency, IF) or in the baseband range (zero IF). The quadrature signal is a complex-valued signal with an inphase component and a quadrature phase component.

The IF/BB signal processing unit filters the quadrature signal and shifts it perhaps spectrally into the baseband, demodulates the baseband signal, and detects the data contained therein and originally transmitted by another transmitting/receiving device.

The HF front-end circuit has an amplifier (low noise amplifier, LNA), connected to the antenna, for amplifying the high-frequency radio signal and a downstream quadrature mixer for converting the amplified signal into the quadrature signal. Furthermore, the HF front-end circuit has a circuit arrangement and a downstream I/Q generator and is connected to the quadrature mixer on the output side.

The circuit arrangement comprises a voltage-controlled oscillator (VCO) according to the invention, whose frequency is set relatively roughly with the use of control voltages and fine tuned with the use of other (optionally PLL-controlled) control voltages.

The I/Q generator derives from the local oscillator signal of the circuit arrangement a differential inphase signal and a differential quadrature phase signal phase-shifted by 90 degrees. Optionally, the I/Q generator comprises a frequency divider, amplifier elements, and/or a unit that assures that the phase offset of the signals is as precisely as possible 90 degrees.

In other advantageous embodiments, the HF front-end circuit has an amplifier (power amplifier) in the transmit path.

The HF front-end circuit and thereby the at least one circuit arrangement of the invention and perhaps parts of the IF/BB signal processing unit are preferably a component of an integrated circuit (IC), which is formed, e.g., as a monolithic integrated circuit using standard technology, for example, in a BiCMOS technology, as a hybrid circuit (thin- or thick-layer technology), or as a multilayer ceramic circuit.

The circuit arrangement of the invention described heretofore by exemplary embodiments is not limited to these exemplary embodiments and can be used advantageously in highly diverse applications, such as, e.g., in oscillator, amplifier, and filter circuits (settable transfer function, bandwidth, etc.).

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An oscillator comprising:
a plurality of excitation units for providing an excitation signal, each excitation unit having at least one inductor; and
a tank as an oscillation generating unit for generating an oscillation signal in response to the excitation signal, the tank having terminals for providing the oscillator signal, the tank being magnetically coupled to the at least one inductor of each excitation unit, and
wherein the excitation signal is transmitted between the excitation units and the tank via the magnetic coupling.

2. The oscillator according to claim 1, wherein each excitation unit and the oscillation generating unit are galvanically separated or connected to at least one nodal point at which a constant potential, particularly a virtual ground, predominates during oscillator operation.

3. The oscillator according to claim 1, wherein each excitation unit comprises an amplifier with at least one inductor, which is provided for the magnetic coupling with at least one inductor of the tank.

4. The oscillator according to claim 1, wherein the tank is formed for tuning z oscillation frequency of the oscillator signal.

5. The oscillator according to claim 1, wherein the terminals for providing the oscillator signal are galvanically separated from each excitation unit or are connected to at least one nodal point at which a constant potential, particularly a virtual ground, predominates during oscillator operation.

6. The oscillator according to claim 1, wherein each excitation unit has a transistor amplifier circuit, a first inductor, and a second inductor, wherein the first and second inductors are connected to the transistor amplifier circuit, wherein the tank has a third inductor and a fourth inductor, wherein the first and third inductors are arranged to provide a first magnetic coupling, and wherein the second and fourth inductors are arranged to provide a second magnetic coupling.

7. The oscillator according to claim 6, wherein the first and second inductors are connected via a nodal point at which a potential is applied and wherein the third and fourth inductors are connected in series.

8. The oscillator according to claim 1, wherein each excitation unit comprises at least one amplifier circuit, wherein the amplifier circuit comprises a first transistor and a second transistor, wherein a first terminal of the first transistor is connected to a control terminal of the second transistor, and wherein a first terminal of the second transistor is connected to a control terminal of the first transistor.

9. The oscillator according to claim 8, wherein the first terminal of the first transistor is connected to a first inductor of the respective excitation unit, wherein the second terminal of the second transistor is connected to a second inductor of the respective excitation unit, and wherein the second terminals of the first and second transistors are connected to one another.

10. The oscillator according to claim 1, wherein the tank or an excitation unit has tunable inductors or capacitors.

11. The oscillator according to claim 1, wherein each excitation unit comprises a first conductive structure, particularly a strip line, wherein the tank comprises a second conductive structure, and wherein the first and second conductive structures are arranged to provide the magnetic coupling.

12. The oscillator according to claim 1, wherein each excitation unit comprises a first conductive structure, which is surrounded at least partially by a second conductive structure of the tank.

13. The oscillator according to claim 1, wherein the tank comprises at least one conductive structure, which surrounds, at least partially, at least one conductive structure of each excitation unit for the magnetic coupling.

14. The oscillator according to claim 11, wherein the conductive structures of each excitation unit are galvanically separated or connected to at least one nodal point at which virtually a constant potential, particularly virtual ground, predominates during operation of the oscillator.
